(19) United States
(12) Patent Application Publication
(10) Pub. No.: US 2012/0146740 A1
(43) Pub. Date: Jun. 14, 2012

(54) SEMICONDUCTOR DEVICE

(75) Inventors: Yoshikazu FURUTA, Kanagawa (JP); Tetsuya Heima, Kanagawa (JP); Kazuaki Hori, Kanagawa (JP)

(73) Assignee: Renesas Electronics Corporation

(21) Appl. No.: 13/309,350

(22) Filed: Dec. 1, 2011

(30) Foreign Application Priority Data
Dec. 9, 2010 (JP) 2010-274377

(51) Int. Cl. H03C 3/02; H03H 7/00

(52) U.S. Cl. 332/144; 333/100

(57) ABSTRACT

The present invention provides a semiconductor device. In the semiconductor device, a signal distributor distributes a high frequency signal generated by an oscillator and inputted to an input part to first and second signals and outputs the same from first and second output parts respectively. A modulator modulates a baseband signal with the first signal and outputs the same therefrom. An offset adjustment unit compares the second signal and the first signal that leaks from the output of the modulator to thereby adjust an offset of the baseband signal. The signal distributor includes a first capacitive element provided between the input part and the first output part, and a second capacitive element provided between the first output part and the second output part. The electrostatic capacitance of the first capacitive element is larger than that of the second capacitive element.

### CROSS-REFERENCE TO RELATED APPLICATIONS

The disclosure of Japanese Patent Application No. 2010-274377 filed on Dec. 9, 2010 including the specification, drawings and abstract is incorporated herein by reference in its entirety.

### BACKGROUND

The present invention relates to a semiconductor device, and particularly to a semiconductor device used in a transmitter.

The development of a multimode RFIC (Radio Frequency Integrated Circuit) corresponding to GSM (Global System for Mobile Communications)/WCDMA (Wideband Code Division Multiple Access) that is a conventional communication standard for a cellular phone, and a 3.9-generation mobile communication system (LTE: Long Term Evolution) that is a next generation high-speed data communications standard has recently been promoted. A multimode transmitter involves problems about a leak of a local oscillation signal (carrier leak) and an image (sideband) signal.

In particular, an FDD (Frequency Division Duplex) system in which transmission and reception are operated simultaneously has been adopted in the WCDMA. For this reason, a problem arises in that receiving band noise of a transmission output leaks into the reception side through a duplexer so that the sensitivity of reception is degraded. A SAW (Surface Acoustic Wave) filter is normally inserted into the output of a transmitter to suppress the receiving band noise, but is high in cost. Therefore, a study of aiming for SAW filter-less form by reducing transmission noise by means of a correction circuit has been carried out actively.

For example, Mirazei and Darabi have reported a SAW filter-less low-noise transmitter configured in the following manner (refer to a Non-Patent Document 1). In the transmitter described in this document, a main signal is transmitted in the order of an LPF (Low Pass Filter), a quadrature modulator and a driver (also called a PA driver) for a power amplifier (PA). A feedback circuit is coupled to the input/output of the PA driver. The feedback circuit is comprised of a detection circuit, a downmixer, an LPF and an upmixer. The detection circuit comprised of a source follower detects an RF signal containing a transmission main signal outputted from the PA driver and RX band noise and transmits the detected RF signal to the downmixer. The down mixer frequency-converts the RF signal using a reception local oscillation signal. Only the receiving band noise is hence extracted from the frequency-converted signal by means of the LPF. The receiving band noise is input to the upmixer where it is frequency-converted again by the reception local oscillation signal, followed by being negative fed back to the input of the PA driver. The negative fed-back RX band noise cancels out the receiving band noise in the output of the PA driver.

A transmitter of a direct upconversion system is accompanied by a problem that when a baseband signal is modulated with a local oscillation signal (carrier) at a quadrature modulator, a carrier leak occurs in which the LO signal leaks into a transmission signal occurs. EVM (Error Vector Magnitude) indicative of an index of the quality of the transmission signal is degraded due to the carrier leak. The carrier leak occurs due to the main cause of a DC (Direct Current) offset at an input terminal for the baseband signal, of the quadrature modulator. For this reason, in order to ensure transmission EVM, there has heretofore been adopted a method of adjusting the DC offset at the baseband-signal input terminal of the modulator to thereby reduce the carrier leak.

A transmission apparatus disclosed in, for example, Japanese Unexamined Patent Publication No. 2009-212869 (Patent Document 1) is equipped with a transmission modulator including a first modulator and a second modulator, a phase comparator and a controller. A first local signal and a second local signal respectively supplied to the first and second modulators are set to a predetermined phase difference (90°). During a calibration operation for reducing a carrier leak, the first local signal or the second local oscillator, and a carrier signal that leaks into the output of the transmission modulator are supplied to the phase comparator. Until the phase comparator detects the predetermined phase difference (90°), the controller adjusts a DC bias current of each paired transistor that configures each modulator.

A description will next be made of an MIM (Metal-Insulator-Metal) capacitor related to the invention of the present application although not directly related to the above. The MIM capacitor is of a capacitive element in which a capacitive insulating layer is configured to be interposed between a pair of electrodes each made up of a metal. The capacitive element has heretofore been configured using a polysilicon layer or an impurity diffusion layer or the like as an electrode. In recent years, however, attention is being given to the MIM capacitor because it is capable of achieving an improvement in the accuracy of capacitance and an improvement in frequency characteristics.

Japanese Unexamined Patent Publication No. 2003-152085 (Patent Document 2) has disclosed a semiconductor device capable of preventing coupling of noise to an MIM capacitor. The semiconductor device described in this document has a semiconductor substrate; a capacitive element formed above the semiconductor substrate and having a lower electrode, a capacitive insulating film formed over the lower electrode, and an upper electrode formed over the capacitive insulating film; a shield layer formed at least above or below the capacitive element; and a lead-out wiring layer formed between the capacitive element and the shield layer and electrically coupled to the lower electrode or the upper electrode. A plurality of holes are formed in the shield layer and the lead-out wiring layer respectively.

### [Related Art Documents]

### [Patent Documents]

[Patent Document 1] Japanese Unexamined Patent Publication No. 2009-212869
[Patent Document 2] Japanese Unexamined Patent Publication No. 2003-152085

### [Non-Patent Document]

[Non-Patent Document 1]

I. A. Mirzaei, H. Darabi, “A Low-Power WCDMA Transmitter with an Integrated Notch Filter”, ISSCC Dig. Tech. Papers, pp. 212-213, February 2008

### SUMMARY

In order to automatically correct a leak of a local oscillation signal and an image signal by an RFIC singly, there is a need to detect non-correction signals such as the local oscillation signal, the image signal, etc. and feed back the same. It is therefore absolutely necessary to place a circuit for detecting the non-correction signals. The detection circuit is required to be designed so as to avoid effects on the performance of a main circuit. It is necessary to set the input impedance of the detection circuit sufficiently higher than that of a node coupled thereto.

It is common that the detection circuit has hitherto been configured by an active circuit having high input impedance. The low-noise transmitter described in the Non-Patent Document 1 by Mirazei and Darabi is provided with a detection circuit comprised of a source follower. In this case, the detection circuit needs to transfer the RF output signal containing the transmission main signal outputted from the PA driver and the RX band noise to the downmixer at low noise without distortion. For this reason, a problem arises in that the detection circuit configured by the active element needs large current due to the request of linearity. Further, a problem arises in that since it is not possible to input the transmission main signal to the downmixer as it is in order to obtain linearity between its input and output, there is a need to provide an attenuator at the output of the detection circuit, whereby a relatively large area is required to install the attenuator.

In the transmission apparatus disclosed in Japanese Unexamined Patent Publication No. 2009-212869 (Patent Document 1), as described above, the phase comparator performs phase detection on the carrier leak of the output of a quadrature modulator and the first and second local oscillation signals. A quadrature modulator using a MOS (Metal Oxide Semiconductor) process needs the input of a local oscillation signal larger than that at a quadrature modulator using a bipolar process. On the other hand, the carrier leak outputted from the quadrature modulator is lower by about −40 dB (about 1/100 times) to about −60 dB (about 1/1000 times) than the local oscillation signal inputted to the quadrature modulator. Since the detected local oscillation signal and the detected output signal of the quadrature modulator are inputted to the phase comparator, wirings for both signals are relatively close to each other at least in the neighborhood of the input of the phase comparator. For this reason, a problem arises in that the accuracy of correction of the carrier leak is degraded because the local oscillation signal overlaps with the output signal of the quadrature modulator in the neighborhood of the input of the phase comparator. Thus, in the detection circuit that detects the local oscillation signal, a problem arises in that the local oscillation signal is required to be attenuated, but current is required even though the signal is attenuated, where the active element is used for the detection circuit.

An object of the present invention is to provide a semiconductor device capable of taking out a detection signal in which a local oscillation signal is attenuated, while suppressing power consumption.

A semiconductor device according to one embodiment of the present invention is equipped with an oscillator, a signal distributor, a modulator and an offset adjustment unit. The oscillator generates a local oscillation signal. The signal distributor has an input part, a first output part and a second output part. The signal distributor distributes the local oscillation signal input to the input part to first and second signals. The signal distributor outputs the first signal from the first output part and outputs the second signal from the second output part. The modulator modulates a baseband signal with the first signal and outputs the same therefrom. The offset adjustment unit compares the second signal and the first signal that leaks from the output of the modulator to thereby adjust an offset of the baseband signal. The signal distributor includes a first capacitive element provided between the input part and the first output part, and a second capacitive element provided between the first output part and the second output part.

A semiconductor device according to another embodiment of the present invention is formed over a semiconductor substrate and equipped with an input part, first and second output parts, and first through third metal films. A high frequency signal is input to the input part. The first and second output parts are provided to output the high frequency signal input to the input part. The first metal film is coupled to the input part. The second metal film is provided between the first metal film and the semiconductor substrate so as to be opposite to the first metal film and is coupled to the first output part. The third metal film is provided between the second metal film and the semiconductor substrate and coupled to the second output part. Here, the interval between the second metal film and the third metal film is larger than that between the first metal film and the second metal film.

According to the semiconductor device according to the above one embodiment, the signal obtained by attenuating the local oscillation signal while suppressing power consumption can be detected by using the signal distributor having the capacitive elements. The signal and the output signal of the modulator are compared with each other, thereby making it possible to suppress the carrier leak of the modulator with accuracy higher than in the conventional case.

According to the semiconductor device according to another embodiment referred to above, it is possible to reduce attenuation of the local oscillation signal input from the input part and output to the first output part and, on the other hand, take out the more attenuated high frequency signal as a detection signal through the second output part.

### BRIEF DESCRIPTION OF THE DRAWINGS

FIG. 1 is a block diagram showing an overall configuration of a communication apparatus 1 equipped with an RFIC 10 according to a first embodiment of the present invention;

FIG. 2 is a block diagram illustrating in further detail a portion related to a carrier leak correction of a quadrature modulator 30 of the RFIC 10 shown in FIG. 1;

FIG. 3 is a block diagram depicting a detailed configuration of a detector 37;

FIG. 4 is a plan view typically showing a structure of each of respective capacitive parts (40 through 43) (plan view of a metal wiring layer M5);

FIG. 5 is a plan view typically showing a structure of each of the capacitive parts (40 through 43) (plan view of a metal wiring layer M3);

FIG. 6 is a plan view typically illustrating a structure of each of the capacitive parts (40 through 43) (plan view of a metal wiring layer M2);

FIG. 7 is a diagram typically showing sections taken along lines VII-VII of FIGS. 4 through 6;

FIG. 8 is an equivalent circuit diagram showing each of the capacitive parts (40 through 43) shown in FIGS. 4 through 7;

FIG. 9 is a diagram showing gain Gain21 from a terminal ND1 to a terminal ND2 and gain Gain31 from the terminal ND1 to a terminal ND3;

FIG. 10 is a diagram illustrating a relationship between an electrical coupling α between an output signal of the quadrature modulator 30 and an output signal of a selector 70, and the amount of a carrier leak;

FIG. 11 is a flowchart showing a procedure for a DC offset correction by a controller 12 shown in FIG. 2;

FIG. 12 is a circuit diagram showing one example illustrative of configurations of switches SW1 and SW2 shown in FIG. 2;

FIG. 13 is a circuit diagram depicting one example of a configuration of the selector 70 shown in FIG. 2;

FIGS. 14(A) and 14(B) are equivalent circuit diagrams, in which FIG. 14(A) shows each of modifications of the capacitive parts (40 through 43) shown in FIG. 3, and FIG. 14(B) shows each of the capacitive parts (40 through 43) shown in FIG. 3;

FIG. 15 is a plan view typically showing a structure of a capacitive part used in an RFIC according to a second embodiment of the present invention (plan view of metal wiring layers M4 and M3);

FIG. 16 is a plan view typically illustrating a structure of the capacitive part used in the RFIC according to the second embodiment of the present invention (plan view of a metal wiring layer M2);

FIG. 17 is a diagram typically showing sections taken along lines XVII-XVII of FIGS. 15 and 16; and

FIG. 18 is an equivalent circuit diagram of the capacitive parts shown in FIGS. 15 through 17.

### DETAILED DESCRIPTION

Preferred embodiments of the present invention will hereinafter be described in detail with reference to the accompanying drawings. Incidentally, the same reference numerals are respectively attached to the same or corresponding components, and their description will not be repeated.

### First Embodiment

### [Overall Configuration of Communication Apparatus 1]

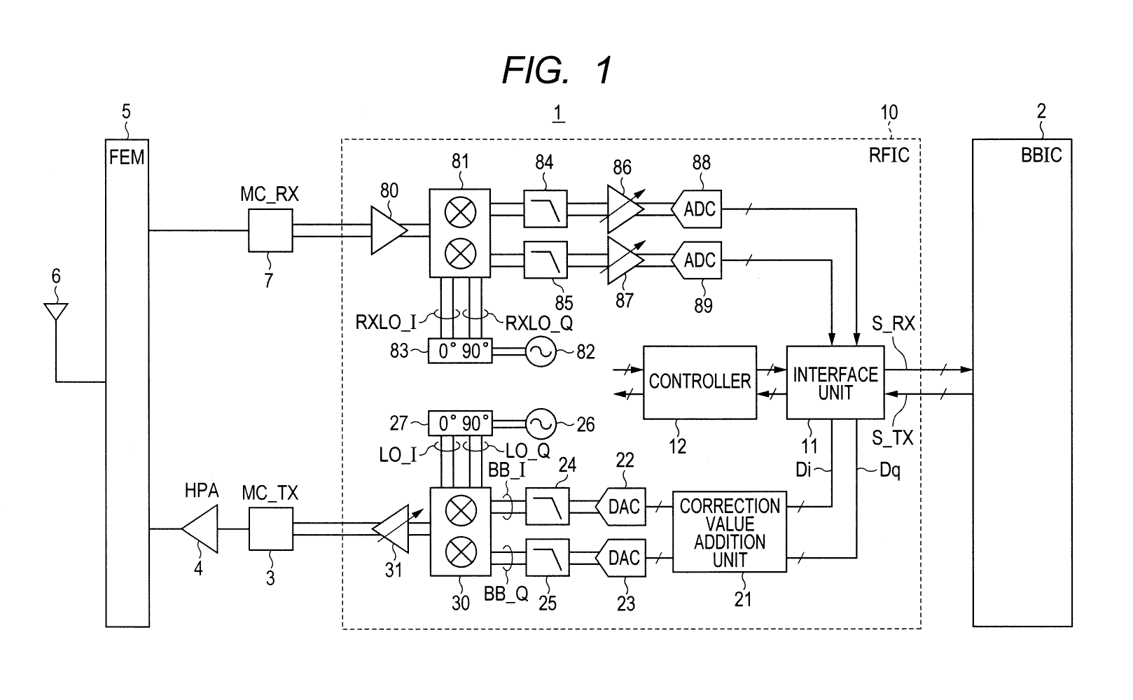

FIG. 1 is a block diagram showing an overall configuration of a communication apparatus 1 equipped with an RFIC 10 according to a first embodiment of the present invention. The communication apparatus 1 includes a baseband circuit 2 (BBIC: Baseband IC), the RFIC 10, a converter 3 which converts the impedance of a differential signal and converts the differential signal to a single-end signal, a high power amplifier 4 (HPA: High Power Amplifier), a front-end module 5 (FEM: Front-End Module), an antenna 6, and a converter 7 which converts a single-end signal to a differential signal and converts the impedance of the differential signal.

Subsequently, the operations of the respective parts will briefly be explained with being separated into at-transmission and at-reception. In the following description, when a non-inversion signal and an inversion signal that configure a differential signal XX are distinguished from each other, the ends of reference numerals XX are respectively marked with T (non-inversion signal) and B (inversion signal). They are described like XX_T and XX_B. Transmission may be described as TX and reception may be described as RX.

At transmission, the baseband circuit 2 first generates an I signal and a Q signal indicative of a quadrature phase component, based on transmission data. The generated I and Q signals are converted to a serial differential signal S_TX together with a control signal to the RFIC 10, followed by being output to the RFIC 10 by LVDS (Low Voltage Differential Signaling). The serial differential signal S_TX is serial-parallel converted by an interface unit 11 of the RFIC 10 from which it is separated into an I signal Di and a Q signal Dq and a control signal to the RFIC 10.

The RFIC 10 includes, as a configuration of a transmitting device, a correction value addition unit 21, DACs 22 and 23 (DAC: Digital-to-Analog Converter), LPFs 24 and 25 (LPF: Low Pass Filter), a local oscillator 26, a phase shifter 27, a quadrature modulator 30, and a TXPGA 31 (PGA: Programmable Gain Amplifier) which controls transmission power. The RFIC 10 includes a transmission mode and a carrier leak calibration mode as operation modes.

The digital I and Q signals Di and Dq outputted from the interface unit 11 are respectively added with first and second offset correction values by the correction value addition unit 21. The offset correction values are used to suppress a carrier leak and are determined in the carrier leak calibration mode.

The DACs 22 and 23 convert the offset-corrected I and Q signals Di and Dq to analog differential signals respectively. The post-offset correction I and Q signals subjected to the analog conversion respectively pass through the LPFs 24 and 25 and are thereafter inputted to the quadrature modulator 30 as differential signals BB_I and BB_Q respectively.

Further, a local oscillation signal LO_I and a local oscillation signal LO_Q corresponding to analog differential signals generated by the phase shifter 27 based on a signal outputted from the local oscillator 26 are inputted to the quadrature modulator 30. Here, the difference in phase between the local oscillation signals LO_I and LO_Q is 90 degrees. The phase of the local oscillation signal LO_Q lags. The local oscillation signals LO_I and LO_Q may be generated by a ½ divider instead of the phase shifter 27.

The quadrature modulator 30 multiplies the BB_I signal and the LO_I signal by each other and multiplies the BB_Q signal and the LO_Q signal by each other. The quadrature modulator 30 performs subtraction on those results of multiplication to thereby generate a transmission modulation signal in a transmission frequency band and outputs the same to the TXPGA 31.

The transmission modulation signal inputted to the TXPGA 31 is adjusted in transmission power according to the control signal, after which it is converted from the differential signal to a single-end signal by the converter 3.

The power amplifier 4 amplifies the transmission signal outputted from the converter 3. The amplified transmission signal is supplied to the antenna 6 through the front-end module 5 and radiated from the antenna 6. The front-end module 5 is a module that includes duplexers for separating transmission and reception signal from each other, and a switch that performs switching of couplings between the duplexers prepared every transmission/reception frequency band and the antenna 6.

Next, at reception, the reception signal received by the antenna 6 is inputted to the converter 7 through the front-end module 5. The converter 7 converts the reception signal corresponding to a single-phase signal into a differential signal and performs impedance conversion thereon, followed by being transmitted to the RFIC 10.

The RFIC 10 includes as a configuration of a receiving device, an LNA 80 (LNA: Low Noise Amplifier), a quadrature demodulator 81, a local oscillator 82, a phase shifter 83, RXPGAs 84 and 85, LPFs 86 and 87 and ADCs 88 and 89 (ADC: Analog-to-Digital Converter).

The reception signal inputted from the converter 7 is amplified by the LNA 80 and thereafter inputted to the quadrature demodulator 81. The quadrature demodulator 81 is inputted with a local oscillation signal RXLO_I and a local oscillation signal RXLO_Q corresponding to analog differential signals generated by the phase shifter 83 based on a signal outputted from the local oscillator 82 in addition to the reception signal of the LNA 80. Here, the difference in phase between the local oscillation signals RXLO_I and RXLO_Q is 90 degrees, and the phase of RXLO_Q lags. The local oscillation signals RXLO_I and RXLO_Q may be generated by a ½ divider instead of the phase shifter 83.

The quadrature modulator 81 multiplies the reception signal and the local oscillation signal RXLO_I by each other to thereby generate a baseband I signal. The quadrature demodulator 81 multiplies the reception signal and the local oscillation signal RXLO_Q by each other to thereby generate a baseband Q signal.

The baseband I and Q signals generated by the quadrature demodulator 81 are respectively level-adjusted by the RXPGAs 86 and 87 after unnecessary waves have been eliminated therefrom by the LPFs 84 and 85. The I and Q signals having passed through the RXPGAs 86 and 87 are respectively converted into digital form by the ADCs 88 and 89. Thereafter, the baseband I signal and the baseband Q signal are converted to a serial differential signal S_RX by the interface unit 11, followed by being outputted to the baseband circuit 2 by LVDS. The baseband circuit 2 demodulates the reception signal, based on the serial differential signal S_RX including the received I and Q signals.

The RFIC 10 further includes a controller 12. The controller 12 controls the respective elements of the transmitting and receiving devices in response to the control signals from the baseband circuit 2, which have been separated by the interface unit 11.

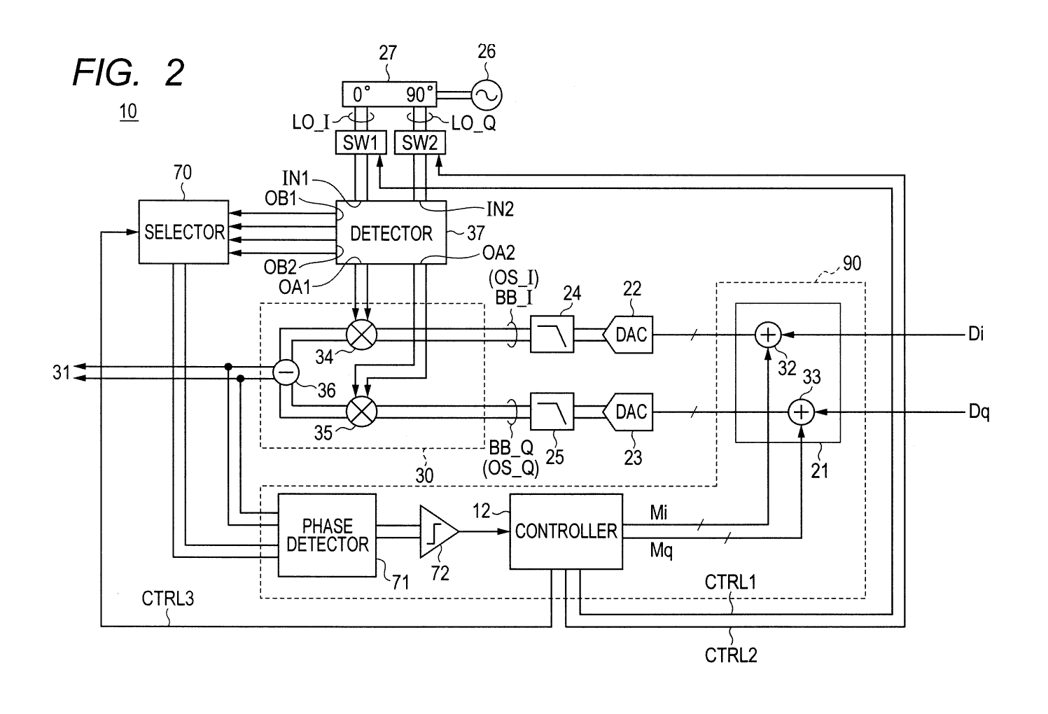

FIG. 2 is a block diagram showing in further detail, parts related to a carrier leak correction of the quadrature modulator 30 in the RFIC 10 shown in FIG. 1. The RFIC 10 further includes switches SW1 and SW2, a detector 37 (signal distributor), a selector 70, a phase detector 71 (PD) and a comparator 72 in addition to the already-explained controller 12, correction value addition unit 21, DACs 22 and 23, LPFs 24 and 25, quadrature modulator 30, local oscillator 26 and phase shifter 27. A more detailed configuration illustrative of the quadrature modulator 30 and the correction value addition unit 21 is also shown in FIG. 2. The phase detector 71, the comparator 72, the controller 12 and the correction value addition unit 21 configure an offset adjustment unit 90 which performs an offset adjustment to the baseband signals Di and Dq at the carrier leak calibration mode.

### [Configuration of Quadrature Modulator 30]

As shown in FIG. 2, the quadrature modulator 30 includes first and second mixers 34 and 35 and a subtractor 36. At transmission, the switches SW1 and SW2 are both controlled to be an on state. At this time, the first mixer 34 multiplies the I signal BB_I and the first local oscillation signal LO_I by each other. The second mixer 35 multiplies the Q signal BB_Q and the second local oscillation signal LO_Q by each other. The subtractor 36 performs subtraction between a differential signal outputted from the first mixer 34 and a differential signal outputted from the second mixer 35 to thereby generate a transmission signal. Each of the mixers 34 and 35 can be configured by, for example, a Gilbert cell circuit.

### [Causes of Carrier Leak and Its Correction Method]

A description will next be made of DC offsets that are principal factors in the carrier leak. Assuming that the frequency of the first local oscillation signal LO_I is f_{L0}, the LO_I signal is expressed in cos (2πf_{L0}×t) (where cos indicates a cosine function, and π indicates the ratio of the circumference of a circle to its diameter) using time t. Here, when a DC offset Vi is contained between input terminals (input terminal for a non-inversion signal and input terminal for an inversion signal) for the baseband I signal, of the mixer 34, the mixer 34 outputs a carrier leak component having a frequency f_{L0} based on a local oscillation signal LO_I expressed in Gc×Vi×cos (2πf_{L0}×t) . . . (1). Here, Gc indicates conversion gain of the mixer 34.

Likewise even on the Q signal side, the LO_Q signal is expressed in sin (2πf_{L0}×t) (where sin indicates a since function) using time t assuming that the frequency of the second local oscillation signal LO_Q is f_{L0}. When a DC offset Vq is contained between input terminals (input terminal for a non-inversion signal and input terminal for an inversion signal) for the Q signal BB_Q, of the mixer 35, the mixer 35 outputs a carrier leak component having a frequency f_{L0} based on a local oscillation signal LO_Q expressed in Gc×Vq×sin(2πf_{L0}×t) . . . (2). Here, Gc indicates conversion gain of the mixer 35. A problem arises in that since the generated carrier leak component is shifted with respect to the origin of modulation signal constellation of a transmission modulation signal, the EVM (Error Vector Magnitude) indicative of a quality index of a transmission signal is degraded.

The DC offsets Vi and Vq that are of the principal factors in the carrier leak occur probabilistically or systematically due to fluctuations in devices configuring differential circuits from the DAC 22 to the mixer 34 and the DAC 23 to the mixer 35, and the difference in parasitic resistance between wirings that couple between the devices, etc. Since the carrier leaks of the outputs of the mixers 34 and 35 become minimal when the DC offsets Vi and Vq are 0, the correction value addition unit 21 is provided in the RFIC 10 to cancel out the DC offsets Vi and Vq. The correction value addition unit 21 includes adders 32 and 33 and adds offset correction values Mi and Mq to the digital I and Q signals Di and Dq respectively in such a manner that voltages of −Vi and −Vq are respectively applied between the input terminals of the mixers 34 and 35. The DC offsets Vi and Vq are adjusted to 0 by this operation so that the carrier leaks are corrected to the optimum.

### [Regarding the Controller 12]

Components related to the DC offset correction will next be explained.

Adjustments to the offset correction values Mi and Mq are performed at the carrier leak calibration mode prior to the transmission of data. In the carrier leak calibration mode, the interface unit 11 of FIG. 1 does not output transmission signals (I signal Di and Q signal Dq). Thus, only signals converted into analog signals, based on the offset correction values Mi and Mq, and DC offset correction signals OS_I and OS_Q based on the DC offsets Vi and Vq from the DAC 22 to the mixer 34 and the DAC 23 to the mixer 35 are inputted to the differential input terminals of the quadrature modulator 30.

The controller 12 monitors output carrier leak signals of the quadrature modulator 30 while changing the offset correction values Mi and Mq, i.e., changing the DC offset correction signals OS_I and OS_Q. Based on the monitored output carrier leak signals, the controller 12 determines such offset correction values Mi and Mq that the amount of a carrier leak reaches the minimum. In order to perform this offset correction, the RFIC 10 is provided with the switches SW1 and SW2, detector 37, selector 70, phase detector 71 and comparator 72.

### [Regarding the Switches SW1 and SW2]

The first switch SW1 is provided on a transmission path for the first local oscillation signal LO_I between the phase shifter 27 and the detector 37. The first switch SW1 is brought to an on state when a control signal CTRL1 outputted from the controller 12 is activated. When it is deactivated, the first switch SW1 is brought to an off state. The second switch SW2 is provided on a transmission path for the second local oscillation signal LO_Q between the phase shifter 27 and the detector 37. The second switch SW2 is brought to an on state when a control signal CTRL2 outputted from the controller 12 is activated. When it is deactivated, the second switch SW2 is changed over to an off state.

The switches SW1 and SW2 are both controlled to be the on state at transmission. On the other hand, in the first embodiment, during the calibration of the first offset correction value Mi, the controller 12 brings the first switch SW1 to the on state and brings the second switch SW2 to the off state. As a result, since the output differential signal of the second mixer 35 becomes zero, signals obtained by frequency-converting the first DC offset correction signal OS_I and the first local oscillation signal LO_I by the first mixer 34 are outputted from the subtractor 36. During the calibration of the second offset correction value Mq, the controller 12 brings the first switch SW1 to the off state and brings the second switch SW2 to the on state. As a result, since the output differential signal of the first mixer 34 becomes zero, signals obtained by frequency-converting the second DC offset correction signal OS_Q and the second local oscillation signal LO_Q by the second mixer 35 are outputted from the subtractor 36.

### [Regarding the Detector 37]

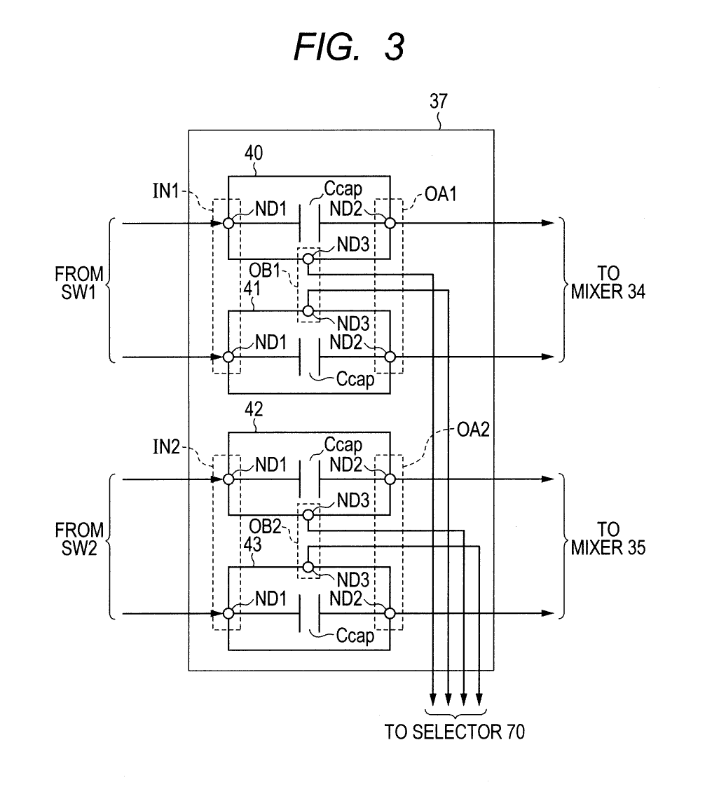

FIG. 3 is a block diagram showing a detailed configuration of the detector 37. The detector 37 is comprised of capacitive parts 40, 41, 42 and 43 each having the same characteristic, which have terminals ND1, ND2 and ND3 respectively. The terminal ND1 is coupled to one end of a capacitive element Ccap and the switches SW1 and SW2. The terminal ND2 is coupled to the other end of the capacitive element Ccap and the mixers 34 and 35. The terminal ND3 is a terminal electromagnetically coupled to the terminals ND2 and ND3. In the first embodiment, the capacitive element Ccap is comprised of an MIM capacitor.

An input part IN1, an output part OA1 and an output part OB1 are respectively configured by the terminals ND1, ND2 and ND3 of the capacitive parts 40 and 41. The local oscillation signal LO_I is inputted to the input part IN1 through the switch SW1. The majority of the local oscillation signal LO_I inputted to the input part IN1 is outputted from the output part OA1 to the mixer 34. A detection signal obtained by attenuating the amplitude of the local oscillation signal LO_I inputted to the input part IN1 is outputted from the output part OB1 to the selector 70. Likewise even with respect to the capacitive parts 42 and 43, an input part IN2, an output part OA2 and an output part OB2 are respectively configured by the terminals ND1, ND2 and ND3 of the capacitive parts 42 and 43. The majority of the local oscillation signal LO_I inputted to the input part IN2 is outputted from the output part OA2 to the mixer 35. A detection signal obtained by attenuating the amplitude of the local oscillation signal LO_Q inputted to the input part IN2 is outputted from the output part OB2 to the selector 70.

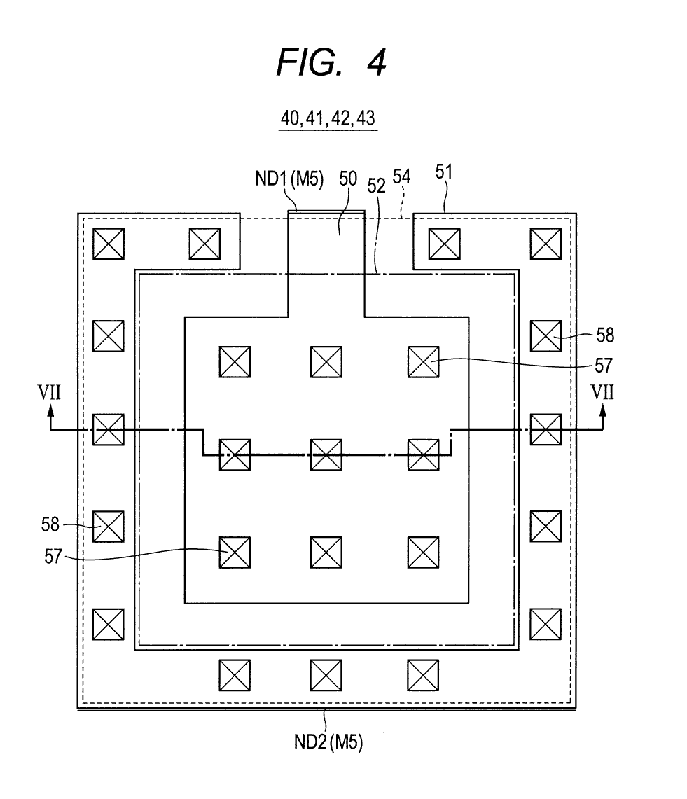

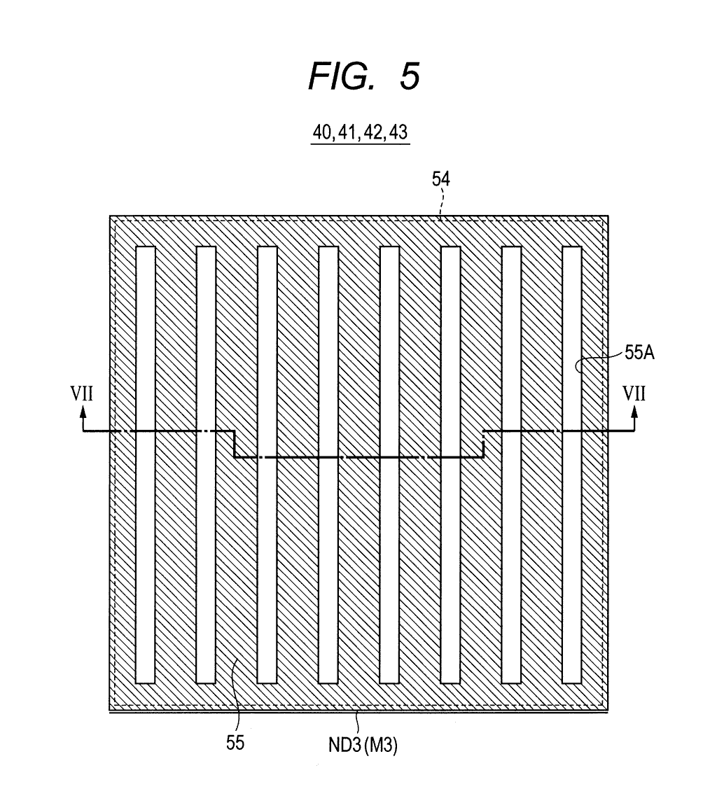

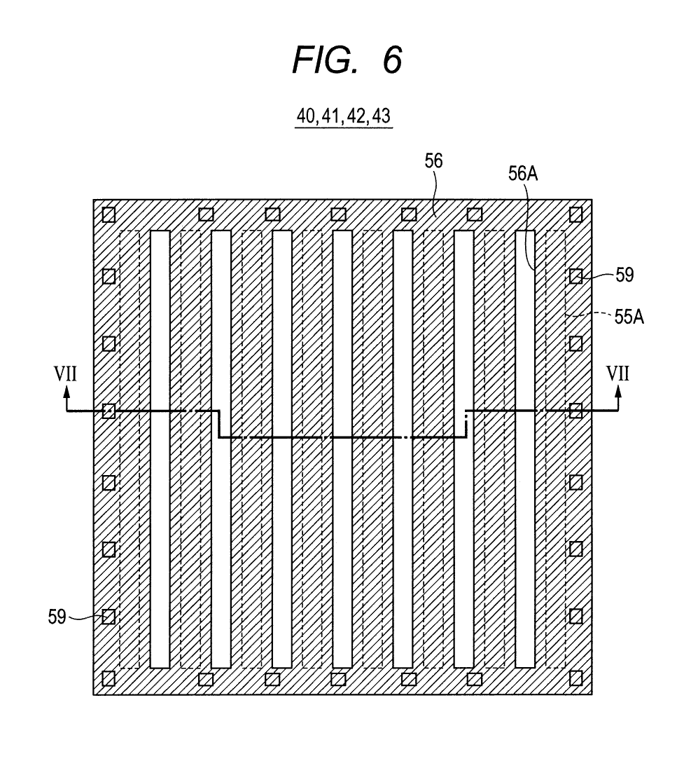

FIGS. 4 through 6 are respectively plan views typically showing structures of the capacitive parts (40 through 43). Each of the capacitive parts is comprised of a plurality of metal electrode films formed in second, third and fifth metal wiring layers M2, M3 and M5, an MIM capacitor formed between a fourth metal wiring layer M4 and the fifth metal wiring layer M5, and via holes for coupling these to one another. A plan view of the fifth metal wiring layer M5 is shown in FIG. 4. A plan view of the third metal wiring layer M3 is shown in FIG. 5. A plan view of the second metal wiring layer M2 is shown in FIG. 6.

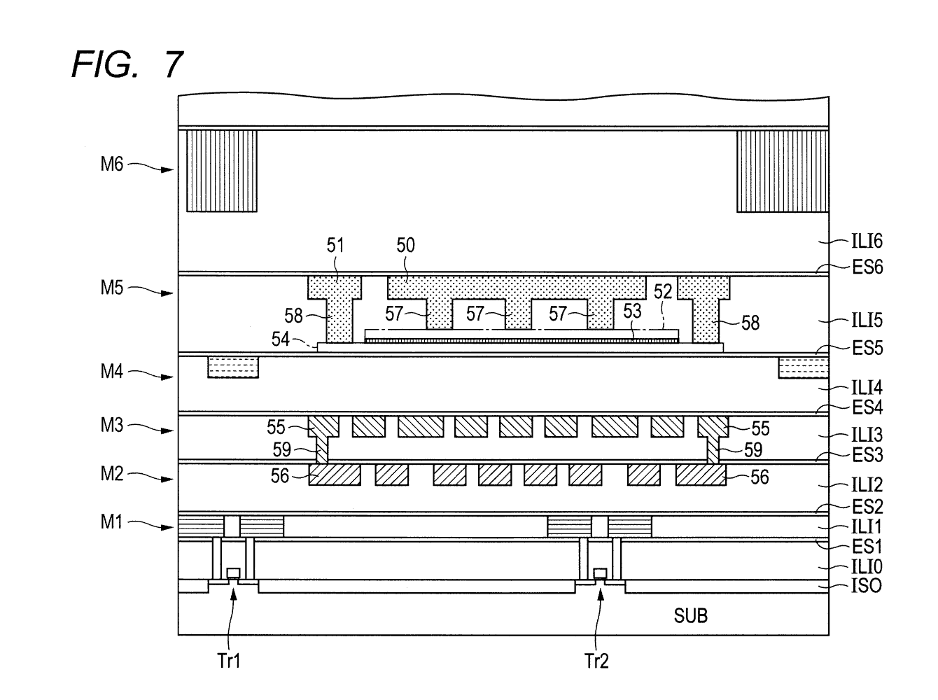

FIG. 7 is a diagram typically showing sections taken along lines VII-VII of FIGS. 4 through 6. The first through sixth metal wiring layers M1 through M6 are shown in FIG. 7 in the order of increasing proximity to a semiconductor substrate SUB. In order to make illustrations easy in FIGS. 4 through 6, the same metal wiring layers are provided with the same hatching, the metal electrode film 52 is indicated by a one-dot chain line, and the metal electrode film 54 is indicated by a broken line. Interlayer insulating films ILI0 through ILI6 are provided between the metal wiring layers and between the metal wiring layer and the semiconductor substrate SUB. Although seventh and subsequent metal wiring layers are actually provided, they are not shown in FIG. 7. Although the metal wiring layers M1, M4 and M6, MOS (Metal Oxide Semiconductor) transistors Tr1 and Tr2 formed in the semiconductor substrate SUB, and a device separation film ISO are not contained in the capacitive parts 40 through 43, they are shown for convenience. The structures of the capacitive parts 40 through 43 will be explained below with reference to FIGS. 4 through 7.

Each of the capacitive parts (40 through 43) includes metal electrode films 50, 51, 55 and 56, the metal electrode film 52 on the upper layer side and the metal electrode film 54 on the lower layer side, which configure the MIM capacitor, and a capacitive insulating film 53 interposed between these metal electrode films 52 and 54.

The metal electrode film 50 is formed in the fifth metal wiring layer M5 and coupled to the metal electrode film 52 of the MIM capacitor through the via holes 57. The metal electrode film 50 and the metal film formed within the via holes 57 are integrally formed by, for example, a Dual Damascene process. The metal electrode film 50 is directly coupled to the terminal ND1 as shown in FIG. 4.

The metal electrode film 51 is formed in the fifth metal wiring layer M5 and coupled to the metal electrode film 54 on the lower layer side of the MIM capacitor through the via holes 58. The metal electrode film 51 and the metal film formed within the via holes 58 are integrally formed by, for example, the Dual Damascene process. The metal electrode film 51 is directly coupled to the terminal ND2 as shown in FIG. 4.

The metal electrode film 52 used in the MIM capacitor is provided at a position opposite to the metal electrode film 54 on the lower layer side. The capacitive insulating film 53 is formed in a region interposed between these metal electrode films 52 and 54. A material higher in dielectric constant than the interlayer insulating films ILI0 through ILI6 is preferably used for the capacitive insulating film 53.

The metal electrode film 55 is formed between the metal electrode film 54 on the lower layer side, which configures the MIM capacitor, and the semiconductor substrate SUB using the third metal wiring layer M3. As shown in FIG. 5, the metal electrode film 55 has a plurality of slit-shaped openings 55A and has a ladder-like form as a whole. The shape of each opening is not limited to one shown in FIG. 5 but may be an arbitrary form. Each of the openings is formed as such a slit as to reach the end of the metal electrode film 55. The metal electrode film 55 may have a comb-like form as a whole. The metal electrode film 55 is directly coupled to the terminal ND3. The metal electrode film 55 is further coupled to the metal electrode film 56 provided at its lower layer, through via holes 59. The metal electrode film 55 and the metal film provided within the via holes 59 are integrally formed by, for example, the Dual Damascene process.

The metal electrode film 56 is formed between the metal electrode film 55 and the semiconductor substrate SUB using the second metal wiring layer M2. As shown in FIG. 6, the metal electrode film 56 has a plurality of slit-shaped openings 56A and has a latter-like form as a whole. The opening 56A of the metal electrode film 56 is provided at a position where it is not overlaid on the opening 55A of the metal electrode film 55 as viewed from the direction perpendicular to the semiconductor substrate SUB. That is, the metal electrode films 55 and 56 are disposed between the metal electrode film 54 on the lower layer side, which configures the MIM capacitor, and the semiconductor substrate SUB with no space therebetween as viewed from the direction perpendicular to the semiconductor substrate SUB. Thus, losses produced by electrically/magnetically coupling between the metal electrode films 50, 51, 52 and 54 and the semiconductor substrate SUB are reduced. The shape of each opening is not limited to one shown in FIG. 6, but may be an arbitrary shape. Each opening may be formed as such a slit as to reach the end of the metal electrode film 56. The metal electrode film 56 may have a comb-like shape as a whole.

The interval between the metal electrode film 54 and the metal electrode film 55 is much larger than that between the metal electrode films 52 and 54 that configure the MIM capacitor. Thus, if the interval between the metal electrode films is set, and the dielectric constant of the capacitive insulating film 53 is set as larger as possible than that of each of the interlayer insulating films ILI1 through IL16, the electrostatic capacitance between the metal electrode films 52 and 54 that configure the MIM capacitor can be set to 100 to 1000 times that between the metal electrode films 54 and 55. That is, the metal electrode film 55 is capacitively coupled to the metal electrode film 54 on the lower layer side, which configures the MIM capacitor, but the magnitude of the electrostatic capacitance thereof is slighter than the MIM capacitor. Incidentally, the metal electrode film 55 is considered to be slightly capacitively-coupled even to the metal electrode film 52 on the upper layer side, which configures the MIM capacitor, but the magnitude thereof is further negligibly small compared with the capacitive coupling to the metal electrode film 54 on the lower layer side. That is, the terminal ND3 is electrically coupled to the terminal ND2 stronger than the terminal ND1.

Although the metal electrode film 55 and the terminal ND3 are directly coupled to each other in FIG. 5, the metal electrode film 56 and the terminal ND3 may be directly coupled to each other instead of the metal electrode film 55. That is, the metal electrode film 55 may be coupled to the terminal ND3 through at least part of the metal electrode film 56.

For example, copper is used as materials for the metal wiring layers M1 through M6 and the metal films lying in the via holes 57, 58 and 59. When, however, the metal films in the via holes 57, 58 and 59 are not fabricated by the Dual Damascene Process, a material different from the metal wiring layers may be used for the metal films in the via holes.

A material smaller in dielectric constant than silicon dioxide (SiO₂), such as a carbon-containing silicon oxide film (SiOC) is preferably used for the interlayer insulating films ILI1 through ILL6 provided in the neighborhood of the capacitive parts 40 through 43. For example, a TEOS film (SiO₂ film formed by CVD (Chemical Vapor Deposition) with tetraethoxysilane and oxygen as material gas) larger in dielectric constant than SiOC is used for the interlayer insulating films provided at layers above the interlayer insulating film ILI0 and the metal wiring layer M6. In FIG. 5, etching stoppers ES2 through ES6 at the Dual Damascene Process are formed over the metal wiring layers M1 through M6. A silicon carbonitride film (SiCN), a silicon carbooxide film (SiCO) or a laminated film of these, or the like is used as a material for the etching stoppers ES2 through ES6.

For example, tungsten, luthenium, a titanium nitride film, titanium, a titanium-titanium nitride film, a tantalum film, a tantalum nitride film, aluminum-copper, copper, aluminum, or a combination of these is used as a material for the metal electrode films 52 and 54 that configure the MIM capacitor. A dielectric material containing silicon, carbon and the like, such as SiOC, an SiO₂ film or the like, or a dielectric material containing Ba, Sr, Pb, Zr, Ti, Ta or the like, such as TaO₂, BST [(Ba, Sr)TiO₃₋ₓ] or the like is used for the capacitive insulating film 53.

In FIG. 7, the interlayer insulating films ILI2, ILI3 and ILI4 are formed with the same thickness. The interlayer insulating film ILI5 is formed with a thickness larger than the thickness of each of the interlayer insulating films ILI2 through ILI4. The thickness relationship is not, however, necessarily required to be set as shown in FIG. 7. For example, the interlayer insulating films ILI2 through ILI5 may be equal to each other in thickness.

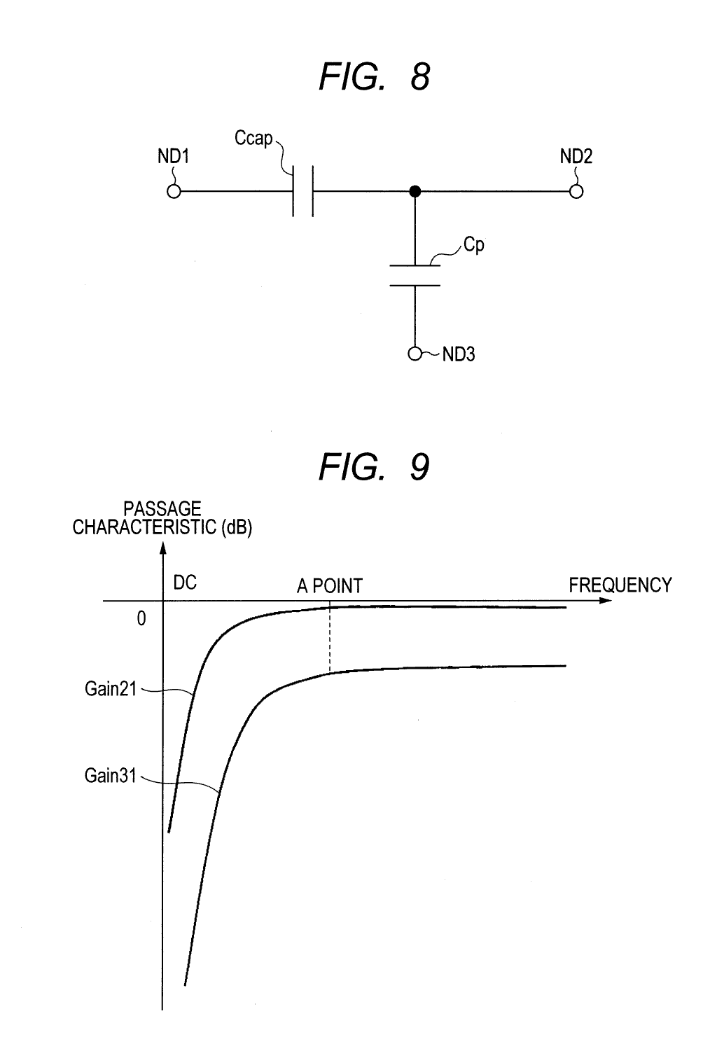

FIG. 8 is an equivalent circuit diagram showing the capacitive parts (40 through 43) shown in FIGS. 4 through 7. If an electrical coupling between the terminals ND3 and ND1 is ignored, the equivalent circuit of each of the capacitive parts (40 through 43) can be described using a capacitive element Ccap corresponding to the MIM capacitor (metal electrode films 52 and 54 and capacitive insulating film 53), and a capacitive element Cp indicating an electrical coupling between the terminals ND2 and ND3, referring to FIG. 8. Thus, a voltage that appears at the terminal ND3 is equal to a voltage attenuated by division of a voltage developed at the terminal ND2 by the capacitive element Cp and the impedance of a circuit coupled to the terminal ND3.

FIG. 9 is a diagram showing gain Gain21 from the terminal ND1 to the terminal ND2 and Gain31 from the terminal ND1 to the terminal ND3. In FIG. 9, the horizontal axis indicates the frequency.

Referring to FIGS. 8 and 9, a signal applied to the terminal ND1 is divided by the capacitance Ccap and circuit impedance coupled to the terminal ND2. Thus, the gain Gain21 has a characteristic greatly attenuated in the neighborhood of DC at which the impedance of the capacitive element Ccap becomes high. Since the impedance of the capacitive element Ccap becomes small as the input signal becomes a high frequency, the gain Gain21 has a small attenuation characteristic.

On the other hand, as described above, the signal that appears at the terminal ND3 is a signal attenuated by further dividing the signal developed at the terminal ND2 by the capacitive element Cp and the circuit impedance coupled to the terminal ND3. Thus, the gain Gain31 is brought to a characteristic analogous to the characteristic curve of the gain Gain21, but reaches a more attenuated characteristic. Since a region in which the gain Gain21 becomes approximately flat is desired on a circuit basis, the frequency of the input signal is preferably a frequency greater than or equal to that at a point A in FIG. 9. Since the electrostatic capacitance of the capacitive element Cp is set smaller than that of the capacitive element Ccap in particular, the signal of the terminal ND3 is more attenuated than the signal of the terminal ND2.

As described above, in response to the first local oscillation signal LO_I and the second local oscillation signal LO_Q respectively outputted form the switches SW1 and SW2, the detector 37 supplies the detection signals in which they are attenuated, to the selector 70 and supplies the signals far smaller in attenuation than the detection signals to the mixers 34 and 35. In order to extract or take out the detection signals in which the local oscillation signals LO_I and LO_Q have been attenuated, the electromagnetic coupling between each of the metal electrode films 55 and 56 provided at the layers below the MIM capacitor, and the MIM capacitor electrode is utilized. Since no active elements are used, the linearity between the input and output is so excellent and power is not consumed or used up. Therefore, the local oscillation signals corresponding to the signals to be detected can be transmitted through the MIM capacitor with almost no loss thereof and supplied to the mixers 34 and 35. Further, the detection signals in which the local oscillation signals have been attenuated can be supplied to the selector 70.

As shown in FIGS. 4 through 7, the capacitive element Ccap is configured as the MIM structure, and the capacitive element Cp is comprised of one electrode (metal wiring layer 54) of the MIM structure, and the wiring layers (M3 and M2) between the one electrode and the semiconductor substrate. It is therefore possible to reduce the area of a layout that configures the capacitive elements Ccap and Cp.

Since the substrate normally has conductivity, an electrically-induced current and a magnetically-induced current are generated in the substrate having conduction when a high frequency signal is transmitted. A problem arises in that the currents are changed to thermal energy due to substrate's resistive components, thereby causing a loss of transmission energy. At least one of the opening and the slit is provided in a plural form in the metal electrode films 55 and 56 provided at the layer below the MIM capacitor, so that the electrical and magnetic couplings between the substrate and the MIM capacitor can be cut off. It is therefore possible to reduce a signal transmission loss due to the substrate.

### [Regarding the Selector 70]

Referring to FIG. 2 again, the selector 70 receives the attenuated first and second local oscillation signals LO_I and LO_Q therein and selects and outputs one of the first local oscillation signal LO_I and the second local oscillation signal LO_Q in accordance with a control signal CTRL3 outputted from the controller 12 at calibration. When the offset correction value Mi corresponding to the I signal Di is adjusted, the controller 12 allows the first local oscillation signal LO_I to be outputted from the selector 70. When the offset correction value Mq corresponding to the Q signal Dq is adjusted, the controller 12 allows the second local oscillation signal LO_Q to be outputted from the selector 70.

### [Regarding the Phase Detector 71 and the Comparator 72]

The phase detector 71 compares the phase of the output signal of the quadrature modulator 30 and the phase of the output signal of the selector 70 and outputs a differential signal corresponding to the difference in phase therebetween. In the first embodiment, the phase detector 71 is comprised of a multiplier and a low-pass filter and outputs 0 when the detected phase difference is 90°.

The comparator 72 compares the output of the phase detector 71 and a predetermined reference value in accordance with a timing signal outputted from the controller 12 and outputs a signal having a high (H) or low (L) logic level to the controller 12 according to the result of comparison. In the first embodiment, the comparator 72 outputs a signal of an H level when the differential output of the phase detector 71 is of a positive value, and outputs a signal of an L level when the differential output is of a negative value. The controller 12 increases or decreases the offset correction value Mi or Mq according to the output voltage of the comparator 72 and finally sets the offset correction value Mi or Mq at the time that it changes from the positive value to the negative value or vice versa, as an offset correction value used at transmission.

### [Regarding the Advantageous Effect of the Detector 37]

The accuracy of the DC offset correction can be enhanced by supplying the local oscillation signals LO_I and LO_Q attenuated by the detector 37 to the phase detector 71 as described above. This reason will next be explained.

In general, a quadrature modulator using a MOS process needs the input of a local oscillation signal larger in amplitude than at a bipolar process. On the other hand, an output carrier leak is made low by about −40 dB ( 1/100 times) to about −60 dB ( 1/1000 times) as compared with the local oscillation signal inputted to the quadrature modulator. Since the local oscillation signal outputted from the selector 70 and the RF signal outputted from the quadrature modulator 30 are inputted to the phase detector 71 in FIG. 2, wirings for these signals are required to be disposed adjacent to each other. To this end, the wiring for each local oscillation signal inputted to the phase detector 71 and the wiring for the RF output signal are electrically coupled to each other. That is, the local oscillation signal detected by the selector 70 and the RF output signal of the quadrature modulator 30 interfere with each other, so that the local oscillation signal leaks into the wiring for the RF output signal. The DC offset correction mechanism of the first embodiment performs phase detection on the carrier leak of the output of the quadrature modulator and the local oscillation signal LO_I or LO_Q to correct the DC offset. For this reason, when the local oscillation signal leaks into the wiring for the RF output signal, the accuracy of correction of the DC offset is degraded.

This will be explained in detail below using mathematical expressions. First assume that the I signal Di, the Q signal Dq and the offset correction values Mi and Mq are all 0. During the calibration of the first offset correction value Mi, the switch SW1 is in an on state and the switch SW2 is in an off state. A carrier leak caused by the DC offset Vi between the differential input terminals (between the non-inversion input terminal and the inversion input terminal), which has been expressed in the equation (1), is outputted from the quadrature modulator 30. On the other hand, a local oscillation signal LO_I given by V sel,out=A×cos(2πf_{L0}×t+Δθ) . . . (3) is selected and outputted by the control signal CTRL3 at the output V sel,out of the selector 70. Here, A in the equation (3) indicates the amplitude of the local oscillation signal LO_I outputted from the selector 70. The phase Δθ indicates the difference in phase between the output of the quadrature modulator 30 and the output of the selector 70, which is generated due to the mixers 34 and 35, subtractor 36, detector 37, selector 70 and wiring parasiticness or the like. Assuming that the amplitude A of the output of the selector 70 is sufficiently larger than that of the output of the quadrature modulator 30, and the output signal of the quadrature modulator 30 and the output signal of the selector 70 are electrically coupled at gain α, a signal given by Vin1=Gc×Vi×cos(2πf_{L0}×t)+A×α×cos(2πf_{L0}×t+Δθ) . . . (4) is inputted to the phase detector 71 as a first input signal Vin1 from the quadrature modulator. A signal given by Vin2=Gc×Vi×α×cos(2πf_{L0}×t)+A×cos(2πf_{L0}×t+Δθ)˜A×cos (2πf_{L0}×t+Δθ) . . . (5) is inputted to the phase detector 71 as a second input signal Vin2 from the selector 70.

Assume that the phase detector 71 is comprised of a multiplier and a low-pass filter. The phase detector 71 outputs a dc component of a signal obtained by multiplying the first input signal Vin1 and the second input signal Vin2 by each other. Since the local oscillation signal LO_I is now selected by the selector 70, the output voltage VPDi of the phase detector 71 is expressed in VPDi=A_{V,PD}×[Gc×Vi×cosΔθ+A×α] . . . (6) by multiplying the right side of the equation (4) and the right side of the equation (5) by each other. Here, the conversion gain of the phase detector 71 is set as A_{V,PD}. In the calculation of the above equation (6), the term of 2×2πf_{L0} also occurs as an angular frequency. This term is however eliminated by the low-pass filter. The first term of the equation (6) is a quantity that changes based on the offset correction value, whereas the second term thereof is a fixed quantity caused by leakage of the local oscillation signal LO_I into the output signal of the quadrature modulator 30 due to the output of the quadrature modulator 30 and the output of the selector 70 being electrically coupled.

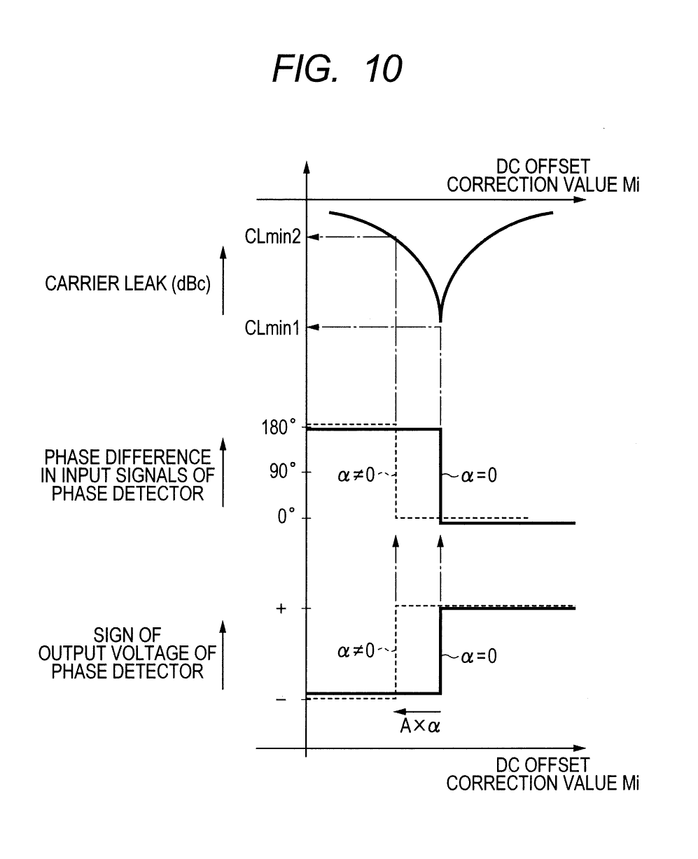

FIG. 10 is a diagram showing a relationship between an electrical coupling α between the output signal of the quadrature modulator 30 and the output signal of the selector 70, and the amount of a carrier leak. In FIG. 10, a relationship between the amount of a carrier leak and a DC offset correction value Mi, a relationship between the difference in phase between input signals of the phase detector 71 and the DC offset correction value Mi, and a relationship between the sign of an output voltage of the phase detector 71 and the DC offset correction value Mi are shown in order from above. The input/output signals of the phase detector 71 are shown in the form of α=0 (ideal state) and α≠0 (actual circuit) are in contradistinction to each other.

Referring to FIG. 10, when the sign of the output of the phase detector 71 is inverted by changing the offset correction value Mi where α=0 (ideal state), the DC offset voltage between the differential input terminals (non-inversion input terminal and inversion input terminal) of the quadrature modulator 30 becomes 0. At this time, the amount of the carrier leak takes a minimum value CLmin1. On the other hand, since the point at which the sign of the output of the phase detector 71 is inverted, is shifted by (−A×α) as shown in the equation (6) where α≠0 (actual circuit), the post-correction amount of carrier leak becomes CLmin2 and hence does not reach the optimal value.

In order to solve this problem, there is a need to perform either of attenuation of the output amplitude A of the selector 70 and a reduction in the electrical coupling α between the output of the quadrature modulator 30 and the output of the selector 70 as apparent from the equation (6). The reduction in the electrical coupling α, however, means that the output wiring of the quadrature modulator 30 and the output wiring of the selector 70 are separated from each other on a layout basis. The cost becomes higher with an increase in the area. It is thus important that the output amplitude A of the selector 70 is adjusted to be as sufficiently small as not to affect the output of the quadrature modulator 30.

The detector 37 used in the RFIC 10 of the first embodiment can suppress the effect to the transmission signal and take out the attenuated signal (i.e., signal reduced in the output amplitude A). Thus, a high-accuracy offset correction can be performed by using the detector 37.

### [Procedure for DC Offset Correction]

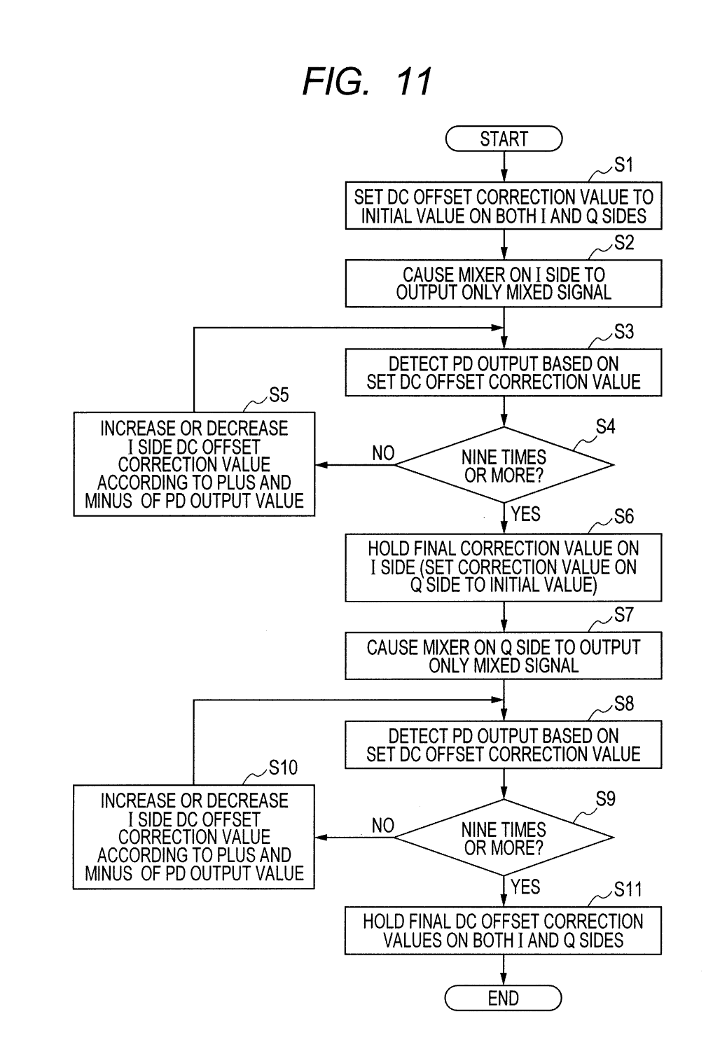

The procedure for the DC offset correction by the controller 12 of FIG. 2 will hereinafter be generalized referring to a flowchart of FIG. 11.

FIG. 11 is a flowchart showing the procedure of the DC offset correction by the controller 12 of FIG. 2. Referring to FIGS. 2 and 11, at Step S1, the controller 12 sets the DC offset correction values Mi and Mq of FIG. 2 to an initial value (0) on both I and Q signal sides.

At the next Step S2, the controller 12 brings the switch SW1 to an on state and brings the switch SW2 to an off state to thereby output the local oscillation signal LO_I to the mixer 34 on the I signal side and avoid the local oscillation signal LO_Q from being output to the mixer 35 on the Q signal side. That is, the controller 12 outputs the mixed signal only to the mixer 34 on the I signal side.

Next, at Step S3, the controller 12 selects the local oscillation signal LO_I on the I signal side by the selector 70 and detects the output of the phase detector 71 at each of the set DC offset correction values Mi and Mq. The DC offset correction value Mq on the Q signal side is constant as the initial value (0). The DC offset correction value Mi on the I signal side is set to a value increased or decreased at Step S5 to be described later after having been set to the initial value (0).

At the next Step S4, the controller 12 determines whether the number of times that the DC offset correction value Mi increases or decreases has reached a predetermined number of times (nine times in FIG. 11). When the predetermined number of times is not reached (the answer is NO at Step S4), the controller 12 proceeds the processing to Step S5.

At Step S5, the controller 12 increases or decreases the DC offset correction value Mi on the I signal side according to the plus and minus of the output voltage of the phase detector 71. When the output voltage of the phase detector 71 is negative, the controller 12 increases the DC offset correction value Mi on the I signal side. When the output voltage of the phase detector 71 is positive, the controller 12 decreases the DC offset correction value Mi on the I signal side. At this time, the controller 12 reduces by half the amount of increase or decrease in the DC offset correction value every number of times as in the case where, for example, the first amount of increase or decrease is “10000000” (the seventh power of 2) in a binary number, and the second amount of increase or decrease is “1000000” (the sixth power of 2) in a binary number. Thus, the eighth amount of increase or decrease becomes “1” in a binary number and can be adjusted to the minimum bit. After the DC offset correction value Mi on the I signal side has been set to the post-increase/decrease value, Step S3 is carried out again.

At Step S4, when the number of time that the DC offset correction value Mi increases or decreases, has reached the predetermined number of times (the answer is YES at Step S4), the controller 12 proceeds the processing to Step S6. At Step S6, the controller 12 holds the final DC offset correction value Mi on the I signal side, which has been increased or decreased at Step S5. The DC offset correction value Mq on the Q signal side is set to the initial value (0).

Next, at Step S7, the controller 12 brings the switch SW1 to an off state and brings the switch SW2 to an on state to thereby output the local oscillation signal LO_Q to the mixer 35 on the Q signal side and avoid the local oscillation signal LO_I from being output to the mixer 34 on the I signal side. That is, the controller 12 outputs the mixed signal only to the mixer 35 on the Q signal side.

At the next Step S8, the controller 12 selects the local oscillation signal LO_Q on the Q signal side by the selector 70 and detects the output of the phase detector 71 at each of the set DC offset correction values Mi and Mq. The DC offset correction value Mi on the I signal side is set to the final offset correction value held at Step S6 and remains unchanged. The initial value of the DC offset correction value Mq on the Q signal side is 0 and the subsequent value is set to a value increased or decreased at Step S10 to be described later.

At the next Step S9, the controller 12 determines whether the number of time that the DC offset correction value Mq on the Q signal side increases or decreases has reached a predetermined number of times (nine times in FIG. 11). When the predetermined number of times is not reached (the answer is NO at Step S9), the controller 12 proceeds the processing to Step S10.

At Step S10, the controller 12 increases or decreases the DC offset correction value Mq on the Q signal side according to the plus and minus of the output voltage of the phase detector 71. When the output voltage of the phase detector 71 is negative, the controller 12 increases the DC offset correction value Mq on the Q signal side. When the output of the phase detector 71 is positive, the controller 12 decreases the DC offset correction value Mq on the Q signal side. At this time, the controller 12 reduces by half the amount of increase or decrease in the DC offset correction value every number of times in a manner similar to the case of Step S5, thereby making it possible to adjust the DC offset correction value to the minimum bit. After the DC offset correction value Mq on the Q signal side has been set to the post-increase/decrease value, Step S8 is executed again.

When the number of the increase or decrease in the DC offset correction value Mq on the Q signal side has reached a predetermined number of times at Step S9 (the answer is YES at Step S9), the controller 12 proceeds the processing to Step S11.

At Step S11, the controller 12 holds the final DC offset correction value Mq on the Q signal side, which has been increased or decreased at Step S10. At this time, the final DC offset value at the increase or decrease at Step S5, is held on the I signal side. The offset correction procedure by the controller 12 is ended in the above-described manner.

### [On Example Illustrative of Detailed Configurations of Switches SW1 and SW2 and Selector 70]

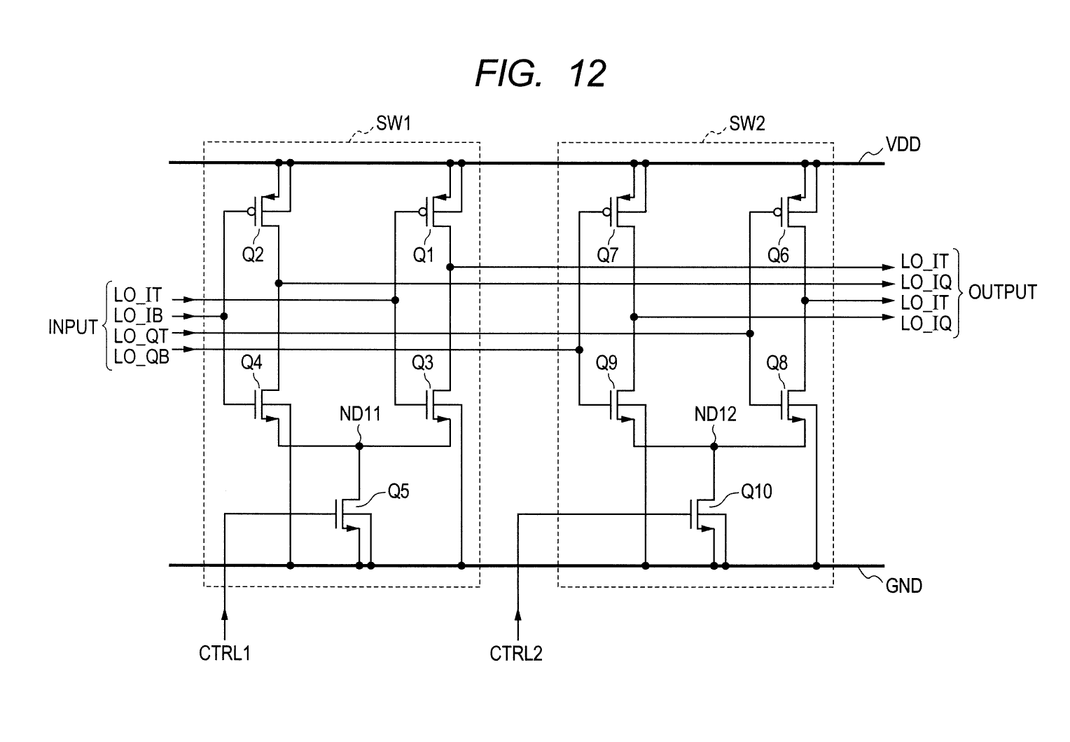

FIG. 12 is a circuit diagram showing one example illustrative of the configurations of the switches SW1 and SW2 shown in FIG. 2

Referring to FIG. 12, the switch SW1 includes PMOS (P-channel Metal Oxide Semiconductor) transistors Q1 and Q2 and NMOS (N-channel Metal Oxide Semiconductor) transistors Q3 through Q5. The PMOS transistor Q1 and the NMOS transistor Q3 configure an inverter and are coupled in series between a power supply line VDD and a node ND11 in this order. A local oscillation signal LO_IT is inputted to the gates of the transistors Q1 and Q3. Likewise, the PMOS transistor Q2 and the NMOS transistor Q4 configure an inverter and are coupled in series between the power supply line VDD and the node ND11 in this order. A local oscillation signal LO_IB is inputted to the gates of the transistors Q2 and Q4.

The NMOS transistor Q5 is coupled between the node ND11 and a ground line GND. A control signal CTRL1 from the controller 12 of FIG. 2 is inputted to the gate of the transistor Q5. Since the transistor Q5 is made conductive when the control signal CTRL1 is a high (H) level, the inverter configured by the transistors Q1 and Q3 and the inverter configured by the transistors Q2 and Q4 are operated. As a result, the local oscillation signal LO_IT is outputted from a connecting node of the transistors Q1 and Q3, and the local oscillation signal LO_IB is outputted from a connecting node of the transistors Q2 and Q4. Since the transistor Q5 is brought to an off state when the control signal CTRL1 is a low (L) level, the inverter configured by the transistors Q1 and Q3 and the inverter configured by the transistors Q2 and Q4 are not both operated. As a result, the local oscillation signals LO_IT and LO_IB are cut off. Since the transistors Q1, Q2, Q6 and Q7 are repeatedly turned on and off in synch with the cycles of the local oscillation signals LO_IT, LO_IB, LO_QT and LO_QB at this time, the outputs of the respective inverters are fixed to an approximately constant voltage (power supply voltage). Incidentally, although not shown in FIG. 12, an inverter for a buffer is further provided on the output side of the switch SW1.

Since the switch SW2 is similar to the switch SW1 in configuration and operation, their description will not be repeated. In the description of the switch SW1, the transistors Q1 through Q5 respectively correspond to the transistors Q6 through Q10, the node ND11 corresponds to a node ND12, and the local oscillation signals LO_IT and LO_IB respectively correspond to the local oscillation signals LO_QT and LO_QB.

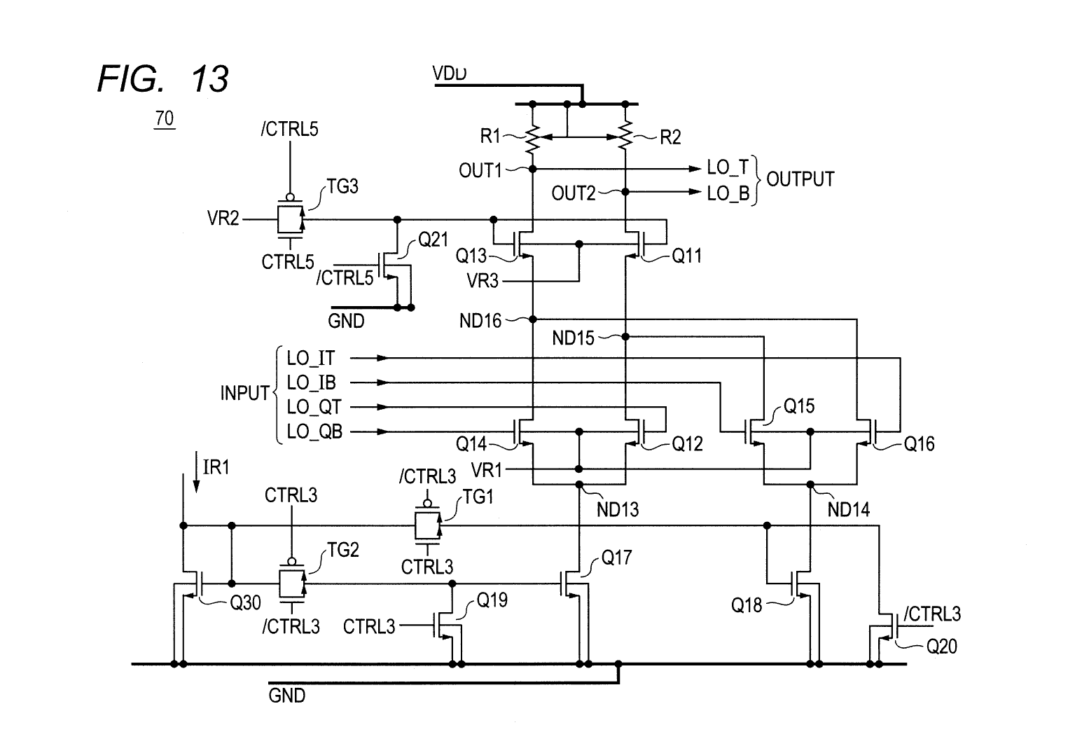

FIG. 13 is a circuit diagram showing one example of the configuration of the selector 70 of FIG. 2. Referring to FIG. 13, the selector 70 includes NMOS transistors Q11 through Q21 and Q30, transmission gates TG1 through TG3 and resistive elements R1 and R2. A description will first be made of couplings among these components.

The resistive element R2 and the transistors Q11 and Q12 are coupled in series between the power supply line VDD and a node ND13 in this order. The resistive element R1 and the transistors Q13 and Q14 are coupled in series between the power supply line VDD and the node ND13 in this order. The transistor Q17 is coupled between the node ND13 and the ground line GND and is used as a current source. The resistive elements R1 and R2 and the transistors Q11 through Q14 and Q17 configure a cascode amplifier circuit. The local oscillation signals LO_QT and LO_QB are respectively inputted to the gates of the differential pair Q12 and Q14. The drains of the transistors Q13 and Q11 are used as output nodes OUT1 and OUT2.

The transistor Q15 is coupled between a connecting node ND15 of the transistors Q11 and Q12 and a node ND14. The transistor Q16 is coupled between a connecting node ND16 of the transistors Q13 and Q14 and the node ND14. The transistor Q18 is coupled between the node ND14 and the ground line GND and is used as a current source. The local oscillation signals LO_IT and LO_IB are respectively inputted to the gates of the differential pair Q16 and Q15. The differential pair Q16 and Q15 share the resistive elements R1 and R2 used as load resistors and the transistors Q11 and Q13 with the differential pair Q12 and Q14. The backgates of the differential pair Q16 and Q15 and the differential pair Q12 and Q14 are supplied with a predetermined bias voltage VR1.

The drain and gate of the diode-coupled transistor Q30 are coupled to the gate of the transistor Q18 through the transmission gate TG1 and coupled to the gate of the transistor Q17 through the transmission gate TG2. Further, the gates of the transistors Q17 and Q18 are respectively grounded through the transistors Q19 and Q20. The backgates of the transistors Q17 through Q20 are grounded.

In the above circuit configuration, when the control signal CTRL3 outputted from the controller 12 is of an H level, the transmission gate TG1 is brought to an on state, and the transmission gate TG2 is brought to an off state. Further, the transistor Q20 is brought to an off state, and the transistor Q19 is brought to an on state. Thus, a reference current IR1 supplied to the drain of the transistor Q30 flows through the transistor Q18. On the other hand, the transistor Q17 becomes an off state. As a result, the local oscillation signals LO_IT and LO_IB respectively supplied to the gates of the differential pair Q16 and Q15 are outputted from the output nodes OUT1 and OUT2.

When the control signal CTRL3 is of an L level, the on and off states are made opposite to the above and hence the local oscillation signals LO_QT and LO_QB respectively supplied to the gates of the differential pair Q12 and Q14 are outputted from the output nodes OUT1 and OUT2.

Incidentally, in order to stop the operation of selection by the selector 70, the gates of the transistors Q11 and Q13 are supplied with a predetermined bias voltage VR2 through the transmission gate TG3 and grounded via the transistor Q21. Further, the backgates of the transistors Q11 and Q13 are supplied with a predetermined bias voltage VR3. Thus, when a control signal CTRL5 is of an H level, the transmission gate TG3 is brought to an on state so that the transistor Q21 is brought to an off state. Therefore, the selector 70 performs a selecting operation. When the control signal CTRL5 is of an L level, the transistors Q11 and Q13 are brought to an off state, so that the output nodes OUT1 and OUT2 are fixed to the H level and the selector 70 stops the selecting operation.

### [Modification]

FIGS. 4 and 7 have explained the example in which the terminal ND1 inputted with the local oscillation signal and the metal electrode film 52 on the upper layer side, which configures the MIM capacitor, are coupled to each other, and the terminal ND2 coupled to the mixers 34 or 35 and the metal electrode film 54 on the lower layer side that configures the MIM capacitor, are coupled to each other. The relationship of coupling between the electrode for the MIM capacitor and the terminals ND1 and ND2 may be opposite to the example shown in each of FIGS. 4 and 7. That is, the terminal ND1 inputted with the local oscillation signal, and the metal electrode film 54 on the lower layer side, which configures the MIM capacitor, may be coupled to each other. The terminal ND2 coupled to either the mixer 34 or the mixer 35, and the metal electrode film 52 on the upper layer side, which configures the MIM capacitor, may be coupled to each other. In this case, the terminal ND3 is electrically tightly coupled to the terminal ND1 rather than the terminal ND2.

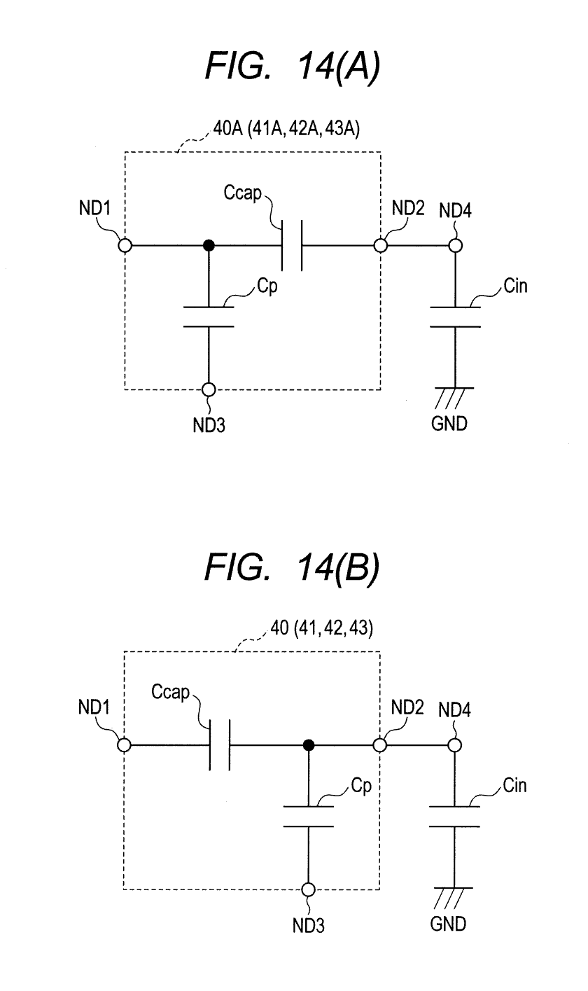

FIGS. 14(A) and 14(B) are respectively equivalent circuit diagrams, in which FIG. 14(A) shows the equivalent circuit diagram illustrative of capacitive parts (40A through 43A) corresponding modifications of the capacitive parts (40 through 43) shown in FIG. 3, and FIG. 14(B) shows the equivalent circuit diagram (identical to FIG. 8) illustrative of the capacitive parts (40 through 43) shown in FIG. 3. In FIGS. 14(A) and 14(B), ND4 indicates an input node of a subsequent-stage circuit (mixer 34 or 35 of FIG. 2) coupled to the terminal ND2 of the capacitive part. Cin indicates an input capacitor of the subsequent-stage circuit. In FIGS. 14(A) and 14(B), the MIM capacitor between the terminals ND1 and ND2 is assumed to be Ccap, the capacitance of coupling between the terminals ND1 and ND3 is assumed to be Cp in FIG. 14(A), and the capacitance of coupling between the terminals ND2 and ND3 is assumed to be Cp in FIG. 14(B).

Assuming that in the case of FIG. 14(A), the voltage of a signal inputted to the terminal ND1 is Vin, a voltage Vout that appears at the input node ND4 of the subsequent-stage circuit is expressed in Vout=Vin×Ccap/(Ccap+Cin) . . . (7). Assuming that the voltage of a signal inputted to the terminal ND1 is Vin in the case of FIG. 14(B), a voltage Vout that appears at the input node ND4 of the subsequent-stage circuit is expressed in Vout=Vin×Ccap/(Ccap+Cp+Cin) . . . (8). It is understood that when the above equations (7) and (8) are compared with each other, the modification shown in FIG. 14(A) is more desirable than the case of FIG. 14(B) because the output voltage Vout becomes large in the case of FIG. 14(A). Since the electrostatic capacitance of the capacitive element Cp is smaller than that of the capacitive element Ccap, the detected signal that appears at the terminal ND3 can be attenuated more than the detected signal that appears at the terminal ND2.

The detector 37 shown in the first embodiment can be used as the detection circuit used in the feedback circuit of the transmitter (refer to the Non-Patent Document 1) reported by Mirazei and Darabi, taking advantage of the characteristic that it has satisfactory linearity between the input and output thereof, as another application example.

### Second Embodiment

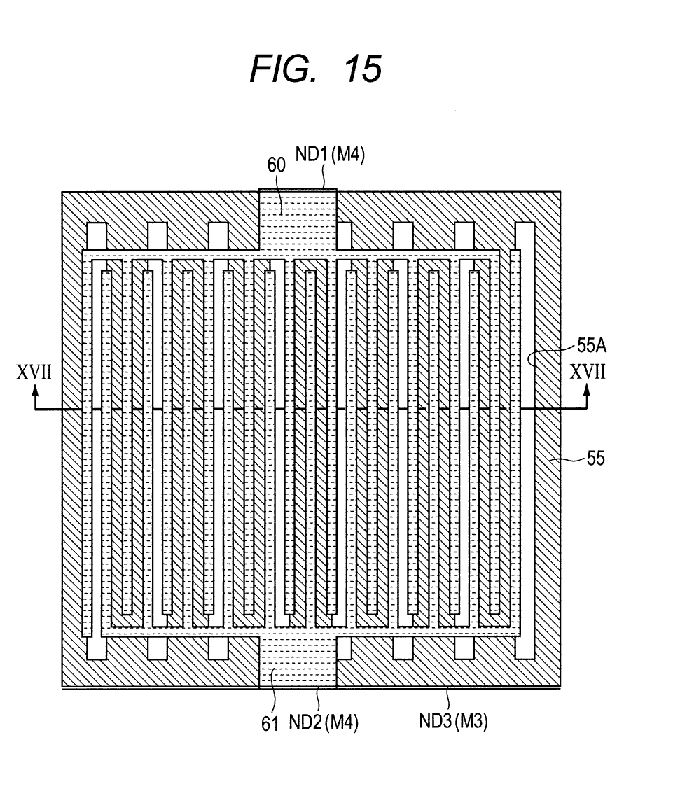

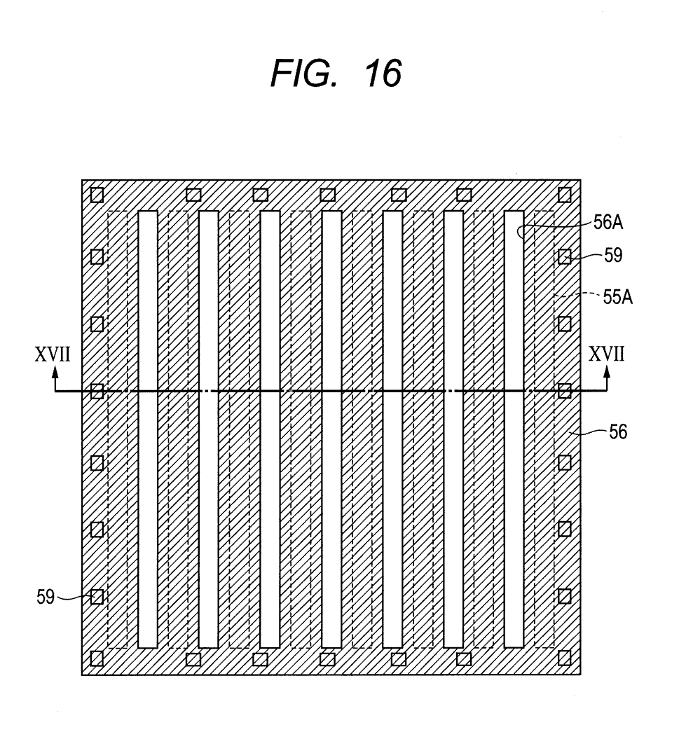

FIGS. 15 and 16 are respectively plan views typically showing a structure of a capacitive part used in an RFIC according to a second embodiment of the present invention. A plan view of a fourth metal wiring layer M4 and a plan view of a third metal wiring layer M3 are shown in FIG. 15 in overlay form. A plan view of a second metal wiring layer M2 is shown in FIG. 16.

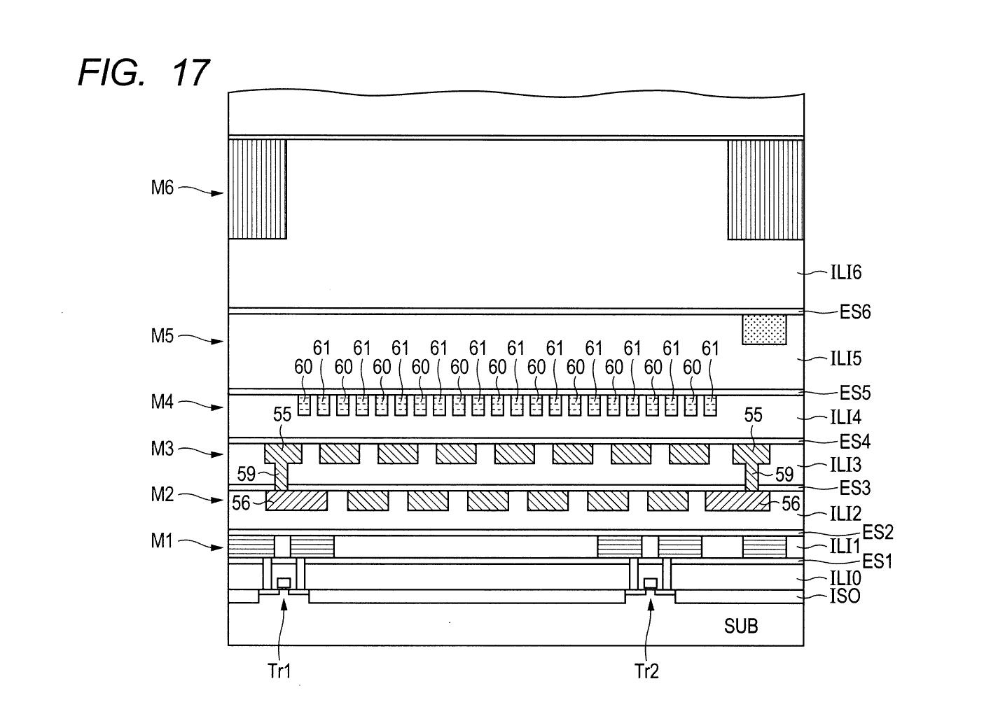

FIG. 17 is a diagram typically showing sections taken along lines XVII-XVII of FIGS. 15 and 16. In FIGS. 15 through 17, the same reference numerals are respectively attached to the same or corresponding components as those in FIGS. 4 through 7, and their description will not be repeated. In order to make illustrations easy in a manner similar to the case of FIGS. 4 through 7, the same metal wiring layers are provided with the same hatching.

Referring to FIGS. 15 through 17, the capacitive part according to the second embodiment is used instead of the capacitive parts shown in FIGS. 4 through 7. Concretely, the capacitive part according to the second embodiment includes metal electrode films 60 and 61 formed in the fourth metal wiring layer M4, a metal electrode film 55 formed in the third metal wiring layer M3, and a metal electrode film 56 formed in the second metal wiring layer M2.

The metal electrode films 60 and 61 respectively have comb-type shaped portions. These comb-type shaped portions are disposed so as to be combined with each other, thereby configuring an inter-digital capacitor. The metal electrode film 60 is directly coupled to a terminal ND1, and the metal electrode film 61 is directly coupled to a terminal ND2. Since the wiring pitch becomes narrow with process miniaturization, the inter-digital capacitor and an MIM capacitor may be used in conjunction with each other in a CMOS (Complementary Metal Oxide Semiconductor) process. A reduction in cost is enabled by configuring the capacitive part using the inter-digital capacitor as an alternative to the MIM capacitor.

Since the structures of the metal electrode films 55 and 56 respectively provided between the metal electrode films 60 and 61 and a semiconductor substrate SUB are identical to those shown in FIGS. 4 through 7, their detailed description will not be repeated. The interval between each of the metal electrode films 60 and 61 that configure the inter-digital capacitor, and the metal electrode film 55 is much larger than that between the metal electrode films 60 and 61. If the interval between the metal electrode films is set in this way and the thickness of each of the metal electrode films 60 and 61 that configure the inter-digital capacitor is made sufficiently large, the electrostatic capacitance between the metal electrode films 60 and 61 that configure the inter-digital capacitor can be set to 100 to 1000 times the electrostatic capacitance between each of the metal electrode films 60 and 61 and the metal electrode film 55. Incidentally, although a terminal ND3 is directly coupled to the metal electrode film 55 in FIG. 15, the terminal ND3 may be directly coupled to the metal electrode film 56.

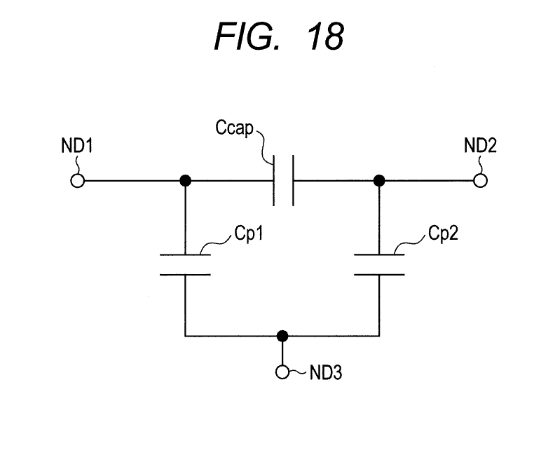

FIG. 18 is an equivalent circuit diagram of the capacitive part shown in FIGS. 15 through 17. Referring to FIG. 18, the equivalent circuit of the capacitive part can be expressed by a capacitive element Ccap corresponding to the inter-digital capacitor (metal electrode films 60 and 61), a capacitive element Cp1 indicative of an electrical coupling between the terminals ND1 and ND3 (between the metal electrode films 60 and 55), and a capacitive element Cp2 indicative of an electrical coupling between the terminals ND2 and ND3 (between the metal electrode films 61 and 55). The electrostatic capacitance of the capacitive element Ccap is larger than the combined capacitance of the capacitive element Cp1 and the capacitive element Cp2. It can also be said that the electrostatic capacitance of the capacitive element Ccap is larger than that of each of the capacitive elements Cp1 and Cp2.

The embodiments disclosed this time are to be considered in all respects as illustrative and not restrictive. The scope of the invention is indicated by the appended claims rather than by the foregoing description, and all changes which come within the meaning and range of the claims and equivalency thereof are intended to be embraced therein.

What is claimed is:

1. A semiconductor device comprising:
an oscillator which generates a local oscillation signal;
a signal distributor comprising an input part, a first output part and a second output part, the signal distributor distributing the local oscillation signal input to the input part to first and second signals, outputting the first signal from the first output part and outputting the second signal from the second output part;
a modulator which modulates a baseband signal with the first signal and outputs the same therefrom; and
an offset adjustment unit which compares the second signal and the first signal that leaks from an output of the modulator to thereby adjust an offset of the baseband signal,
wherein the signal distributor comprises a first capacitive element provided between the input part and the first output part, and a second capacitive element provided between the first output part and the second output part.

2. A semiconductor device comprising:
an oscillator which generates a local oscillation signal;
a signal distributor comprising an input part, a first output part and a second output part, the signal distributor distributing the local oscillation signal input to the input part to first and second signals, outputting the first signal from the first output part and outputting the second signal from the second output part;
a modulator which modulates a baseband signal with the first signal and outputs the same therefrom; and
an offset adjustment unit which compares the second signal and the first signal that leaks from an output of the modulator to thereby adjust an offset of the baseband signal,
wherein the signal distributor comprises a first capacitive element provided between the input part and the first output part, and a second capacitive element provided between the input part and the second output part.

3. A semiconductor device comprising:
an oscillator which generates a local oscillation signal;
a signal distributor comprising an input part, a first output part and a second output part, the signal distributor distributing the local oscillation signal input to the input part to first and second signals, outputting the first signal from the first output part and outputting the second signal from the second output part;
a modulator which modulates a baseband signal with the first signal and outputs the same therefrom; and
an offset adjustment unit which compares the second signal and the first signal that leaks from an output of the modulator to thereby adjust an offset of the baseband signal,
wherein the signal distributor comprises a first capacitive element provided between the input part and the first output part, a second capacitive element provided between the input part and the second output part, and a third capacitive element provided between the first output part and the second output part.

4. A semiconductor device according to claim 1, which is formed over a semiconductor substrate,
wherein the signal distributor comprises:
a first metal film coupled to the input part;
a second metal film which is provided between the first metal film and the semiconductor substrate so as to be opposite to the first metal film and which is coupled to the first output part and configures the first capacitive element together with the first metal film; and
a third metal film which is provided between the second metal film and the semiconductor substrate and which is coupled to the second output part and configures the second capacitive element together with the second metal film.

5. A semiconductor device according to claim 2, which is formed over a semiconductor substrate,
wherein the signal distributor comprises:
a first metal film coupled to the first output part;
a second metal film which is provided between the first metal film and the semiconductor substrate so as to be opposite to the first metal film and which is coupled to the input part and configures the first capacitive element together with the first metal film; and
a third metal film which is provided between the second metal film and the semiconductor substrate and which is coupled to the second output part and configures the second capacitive element together with the second metal film.

6. A semiconductor device according to claim 3, which is formed over a semiconductor substrate,
wherein the signal distributor comprises first and second metal films which respectively have comb-type shaped portions and configure an inter-digital capacitor as the first capacitive element,
wherein the first and second metal films are respectively coupled to the input part and the first output part, and
wherein the signal distributor further comprises a third metal film which is provided between the first and second metal films and the semiconductor substrate and coupled to the second output part, said third metal film configuring the second capacitive element together with the first metal film and configuring the third capacitive element together with the second metal film.

7. A semiconductor device according to any one of claims 1 to 3, wherein an electrostatic capacitance of the first capacitive element is larger than an electrostatic capacitance of the second capacitive element.

8. A semiconductor device formed over a semiconductor substrate, comprising:
an input part to which a local oscillation signal is input;
first and second output parts for outputting the local oscillation signal input to the input part;
a first metal film coupled to the input part;
a second metal film provided between the first metal film and the semiconductor substrate so as to be opposite to the first metal film, and coupled to the first output part; and
a third metal film provided between the second metal film and the semiconductor substrate and coupled to the second output part,
wherein an interval between the second metal film and the third metal film is larger than an interval between the first metal film and the second metal film.

9. A semiconductor device formed over a semiconductor substrate, comprising:
an input part to which a local oscillation signal is input;
first and second output parts for outputting the local oscillation signal input to the input part;
a first metal film coupled to the first output part;
a second metal film provided between the first metal film and the semiconductor substrate so as to be opposite to the first metal film, and coupled to the input part; and
a third metal film provided between the second metal film and the semiconductor substrate and coupled to the second output part,
wherein an interval between the second metal film and the third metal film is larger than an interval between the first metal film and the second metal film.

10. A semiconductor device formed over a semiconductor substrate, comprising:
an input part to which a local oscillation signal is input;
first and second output parts for outputting the local oscillation signal input to the input part; and
first and second metal films which respectively have comb-type shaped portions and configure an inter-digital capacitor,
wherein the first and second metal films are respectively coupled to the input part and the first output part,
wherein the semiconductor device further comprises a third metal film provided between the first and second metal films and the semiconductor substrate and coupled to the second output part, and
wherein an interval between each of the first and second metal films and the third metal film is larger than an interval between the first metal film and the second metal film.

11. A semiconductor device according to any one of claims 8 to 10, wherein the third metal film is formed with at least one of a slit and an opening in plural form.

12. A semiconductor device according to claim 11, further comprising a fourth metal film provided between the third metal film and the semiconductor substrate and coupled to the third metal film through via holes,
wherein the fourth metal film is formed with at least one of a slit and an opening in plural form at a position where the slit and the opening are not superimposed on both the slit and opening formed in the third metal film as viewed from the direction perpendicular to the semiconductor substrate.
